(19) United States
(12) Patent Application Publication
(10) Pub. No.: US 2016/0126430 A1
(43) Pub. Date: May 5, 2016

(54) LIGHT-EMITTING DEVICE WITH HARDENED ENCAPSULANT ISLANDS

(71) Applicant: Avago Technologies General IP (Singapore) Pte. Ltd, Singapore (SG)

(72) Inventors: Keat Chuan Ng, Penang (MY); Kiam Soon Ong, Penang (MY); Kheng Leng Tan, Penang (MY)

(21) Appl. No.: 14/531,782

(22) Filed: Nov. 3, 2014

(51) Int. Cl. H01L 33/54; H01L 27/15

(52) U.S. Cl. CPC H01L 33/54; H01L 27/15

(57) ABSTRACT

In one embodiment, a light-emitting device having a light source die, a substantially transparent encapsulant surrounding the light source die, and a second substantially transparent encapsulant at least partially covering the first substantially transparent encapsulant is disclosed. The second substantially transparent encapsulant may expose a portion of the first substantially transparent encapsulant. The second substantially transparent encapsulant may be less tacky, and may be hardened as compared to the first substantially transparent encapsulant. The second substantially transparent encapsulant may comprise a plurality of encapsulant islands that are distanced away from one another. In another embodiment, the light-emitting device may comprise a third substantially transparent encapsulant covering a portion of the first substantially transparent encapsulant that is exposed by the second substantially transparent encapsulant.

### BACKGROUND

A light-emitting diode (referred to hereinafter as LED) represents one of the most popular light-emitting devices today. In recent years, the luminous efficacy of LEDs, defined in lumens per Watt, has increased significantly from 20 lumens per Watt (approximately the luminous efficacy of an incandescent light bulb) to over 500 lumens per Watt, which greatly exceeds the luminous efficacy of a fluorescent light at 60 lumens per Watt. In addition to the luminous efficacy, LEDs may be superior or preferable compared to traditional light sources because of their small form factor. With such a small form factor, an optical lens may be placed close to the light sources. Various optical designs that were not possible with traditional light sources may become possible for the LEDs. With new optical designs, LEDs may become one of the most appealing light sources nowadays. As a result, LEDs are finding their ways to almost all applications that utilize light.

Usually, LEDs are covered by epoxy or silicone. A hardened epoxy or silicone may crack and cause delamination when exposed to heat and thermal stress. On the other hand, a more flexible epoxy or silicone may be tacky and attract dust. Over time, the dust may block the light. For applications where the LEDs are used in a covered housing, the tackiness may be less an issue as the LEDs may be protected within a housing, slowing down the dust collection. However, for some applications such as large-scale infotainment displays where the LEDs may be exposed to air, the tackiness of the LED may become challenging to deal with. These applications require the LEDs to have high reliability performance For example, infotainment display systems may be placed on driveways in a desert, exposing the LEDs to high heat during daytime, and cold temperature during night in dusty environment.

### BRIEF DESCRIPTION OF THE DRAWINGS

Illustrative embodiments by way of examples, not by way of limitation, are illustrated in the drawings. Throughout the description and drawings, similar reference numbers may be used to identify similar elements. The drawings may be simplified illustrative views rather than precise engineering drawings. The drawings are for illustrative purpose to assist understanding and may not necessarily be drawn per actual scale.

FIG. 1 shows an illustrative block diagram of a light-emitting device;

FIG. 2A illustrates a cross-sectional view of a light-emitting device having a second substantially transparent encapsulant covering partially an illumination surface of a first substantially transparent encapsulant;

FIG. 2B illustrates a top view of the light-emitting device shown in FIG. 2A;

FIG. 3A illustrates a cross-sectional view of a light-emitting device having a second substantially transparent encapsulant and a third substantially transparent encapsulant covering an illumination surface of a first substantially transparent encapsulant;

FIG. 3B illustrates a top view of the light-emitting device shown in FIG. 3A;

FIG. 3C illustrates a manufacturing process showing how the light-emitting device shown in FIG. 3A may be formed;

FIG. 4A illustrates a cross-sectional view of a light-emitting device having droplets of a second substantially transparent encapsulant covering an illumination surface of a first substantially transparent encapsulant;

FIG. 4B illustrates a top view of the light-emitting device shown in FIG. 4A;

FIG. 5A illustrates a cross-sectional view of a lamp-LED type of light-emitting device having droplets of a second substantially transparent encapsulant covering an illumination surface of a first substantially transparent encapsulant;

FIG. 5B illustrates a top view of the light-emitting device shown in FIG. 5A; and

FIG. 6 illustrates an embodiment of a display system.

### DETAILED DESCRIPTION

Light-emitting devices may be implemented by using various packaging technologies such as a plastic leaded chip carrier (herein after PLCC) package, a ball grid array package (herein after BGA), a pin grid array package (herein after PGA), a quad flat pack (herein after QFP), a printed circuit board (herein after PCB) package and so on. Certain packages, for example PLCC packages, may comprise a lead frame over a molded polymer material such as Polyphthalamide (herein after PPA), Polyamide or Epoxy resin encapsulant like MG 97. For surface mount type, leads extending from the lead frame may be bent so that the light-emitting devices can be soldered on a substrate without through-holes. Light-emitting devices based on other packaging technologies such as a BGA and PGA may comprise a substrate having conductive traces without a lead frame. In this specification, various embodiments of LED are illustrated. Teachings throughout the specification about an LED may be applicable to a light source packaging including, but not limited to, all types of packaging technologies discussed above. In addition, a light-emitting device should not be limited to devices for lighting purposes, but also other optical device that may emit a radiation of invisible light. For example, a light-emitting device may comprise a proximity sensor, an encoder or other optical device involving an emitter configured to emit a visible or invisible light.

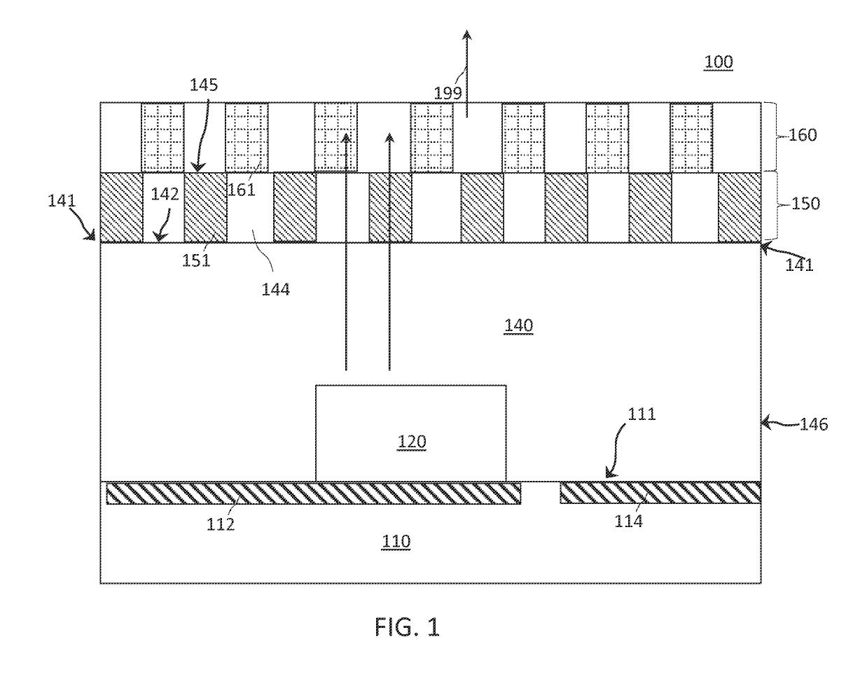

FIG. 1 shows an illustrative block diagram of a light-emitting device 100. The light-emitting device 100 may comprise a body 110, a light source die 120, a first substantially transparent encapsulant 140 encapsulating the light source die 120, a second substantially transparent encapsulant 150, and a third substantially transparent encapsulant 160. The first substantially transparent encapsulant 140 may be encapsulating the light source die 120 and at least a portion of the body 110. As shown in FIG. 1, the first substantially transparent encapsulant 140 may be covering, surrounding, completely encapsulating the light source die 120.

A “body” 110 as used herein in reference to a component of a light-emitting device 100 may refer to a respective primary structure, which provides structural support for other components of the light-emitting device 100. The body 110 may comprise a plurality of conductors 112, 114. In one embodiment, the body 110 may be a substrate such as a PCB.

In another embodiment, the body 110 may be a lead frame molded base portion that may be highly reflective. The body 110 may reflect more than 90% of light or radiation falling on the body 110. The body 110 may be formed using an opaque material such as polyamide, epoxy resin, plastic and other similar material. The body 110 may be formed encapsulating or surrounding the plurality of conductors 112, 114 using an injection mold or other similar process. The body 110 may be configured to direct light emitted from the light source die 120 towards an illumination direction 199. For example, the body 110 may comprise a reflective surface 111 facing the illumination direction 199 such that the reflective surface 111 may be configured to direct light towards the illumination direction 199. In another embodiment, the body 110 may comprise a reflector cup (not shown) configured to direct light towards the illumination direction 199.

In yet another embodiment, the body 110 may be the plurality of conductors 112, 114 configured to hold the light source die 120 and configured to provide structural support for the light-emitting device 100. Examples of these types of light-emitting device 100 may comprise metal substrate LEDs and/or lamp LEDs. Lamp LEDs may have two leads, where one lead comprises a reflector cup (not shown) to hold the light source die 120 and another lead is configured to receive a wire bond from the light source die 120.

In the embodiment shown in FIG. 1, the plurality of conductors 112, 114 may be made of electrically and thermally conductive material, such as steel, copper, metal or a metal alloy, a metal compound or other similar material. The plurality of conductors 112, 114 may be formed using any stamping, cutting, etching or other similar process that is known in the art. For surface mount purposes, the plurality of conductors 112, 114 may be bent to define a bottom portion for attaching to external surfaces (not shown).

The light source die 120 may be a light source or a radiation source such as an LED configured to emit a radiation. The light source die 120 may be configured to emit electromagnetic radiation waves that may be invisible to human eyes such as infrared, ultra-violet or radiation having other invisible wavelength. Alternatively, the light source die 120 may be configured to emit electromagnetic radiation of visible wavelength.

The first substantially transparent encapsulant 140 may be substantially transparent. In one embodiment, the first substantially transparent encapsulant 140 may have approximately more than ninety percent of transmissivity, e.g., allowing more than ninety percent of light to be transmitted through the first substantially transparent encapsulant 140. The first substantially transparent encapsulant 140 may comprise substantially silicone material, epoxy or other substantially transparent material. The first substantially transparent encapsulant 140 may be encapsulating the light source die 120, at least a portion of the body 110, and at least a portion of the plurality of conductors 112, 114. The first substantially transparent encapsulant 140 may be configured to cover and provide protection to the light source die 120 from external forces. The first encapsulant may also shield the light source die 120 from corrosions that may be caused by external substances.

The first encapsulant 140 may comprise an illumination surface 142. The illumination surface 142 may be positioned between the light source die 120 and the illumination direction 199. The light emitted by the light source die 120 may be transmitted through the illumination surface 142 towards the illumination direction 199. The illumination surface 142 may be substantially perpendicular to the illumination direction 199 and may be positioned facing the illumination direction 199. The illumination surface 142 may have an outer perimeter 141 circumscribing the illumination surface 142. In one embodiment, the illumination surface 142 may comprise a lens surface configured to collimate light towards the illumination direction 199. The outer perimeter 141 of the illumination surface 142 may be the outer perimeter 141 of the lens surface.

The second substantially transparent encapsulant 150 may be partially (but not completely) covering the first substantially transparent encapsulant 140. In one embodiment, the second substantially transparent encapsulant 150 may be leaving at least a portion of the first substantially transparent encapsulant 140 exposed. The second substantially transparent encapsulant 150 may partially cover the first substantially transparent encapsulant 140 such that the first substantially transparent encapsulant 140 is exposed externally, but not accessible by an external user. The second substantially transparent encapsulant 150 may have approximately more than ninety percent of transmissivity. The second substantially transparent encapsulant 150 may comprise substantially silicone material, epoxy or other substantially transparent material.

The area of the illumination surface 142 covered by the second substantially transparent encapsulant 150 may be less susceptible to attracting dust. Therefore, it may be beneficial to cover more area of the illumination surface 142 using the second substantially transparent encapsulant 150. In the embodiment shown in FIG. 1, the second substantially transparent encapsulant 150 may be covering more than 50% of the illumination surface 142 of the first substantially transparent encapsulant 140. In one embodiment, the second substantially transparent encapsulant 150 may be covering more than 90% of the illumination surface 142 of the first substantially transparent encapsulant 140. The second substantially transparent encapsulant 150 may comprises a plurality of first encapsulant islands 151. The plurality of first encapsulant islands 151 may be substantially rectangular or square shape. In one embodiment, the second substantially transparent encapsulant 150 may comprise a plurality of transparent droplets having a substantially circular shape. The plurality of first encapsulant islands 151 may be distanced away from each other such that a gap is arranged between the plurality of first encapsulant islands 151. In one embodiment, the plurality of first encapsulant islands 151 may be distanced away from each other by less than about 3 mm such that the first substantially transparent encapsulant 140 is exposed externally but not accessible by a user. The plurality of first encapsulant islands 151 may be arranged in a two dimensional plane. For example, the plurality of first encapsulant islands 151 may be arranged in a uniformly spaced two-dimensional matrix.

The second substantially transparent encapsulant 150 may differ from the first substantially transparent encapsulant 140 at least in that the second substantially transparent encapsulant 150 may be less tacky compared to the first substantially transparent encapsulant 140. The word “tacky” as used herein may mean, “retaining a sticky feel”. A first material that is less tacky as compared to a second material may have a lower coefficient of static friction relative to the second material. A material that is “tacky” may be stickier and may have a higher tendency to attract dust compared to another material that is less “tacky”. Alternatively or additionally, tackiness of a material may relate to the strength of chemical bonds between the material and another material (of the same or different type). A tackier material may establish stronger or more difficult to break chemical bonds with a second material as compared to a less tacky material that establishes a weaker or easier to break chemical bond with the same second material. Alternatively or additionally, tackiness of a material may relate to the coefficient of static and/or dynamic friction associated with the material. A tackier material may have a higher coefficient of static and/or dynamic friction as compared to a less tacky material that has a lower coefficient of static and/or dynamic friction.

In addition, the second substantially transparent encapsulant 150 may be hardened as compared to the first substantially transparent encapsulant 140. The second substantially transparent encapsulant 150 may be substantially harder as compared to the first substantially transparent encapsulant 140. For example, the first substantially transparent encapsulant 140 may be compressed and may be deformed temporarily when a sufficiently large external force is applied. However, the second substantially transparent encapsulant 150 may be substantially less susceptible to such external disturbance. The second substantially transparent encapsulant 150 may be more brittle than the first substantially transparent encapsulant 140.

The configuration shown in FIG. 1 may be advantageous for several reasons. The first substantially transparent encapsulant 140 may be encapsulating the light source die 120 instead of the second substantially transparent encapsulant 150. The first substantially transparent encapsulant 140 may be more flexible and may absorb stress caused by a thermal expansion. However, as a substantially large portion of the illumination surface 142 of the first substantially transparent encapsulant 140 may be covered by the second substantially transparent encapsulant 150, the light-emitting device 100 may not attract dust as easily as other light-emitting device (not shown) that does not have the second substantially transparent encapsulant 150. The first substantially transparent encapsulant 140 may be more tolerance towards thermal expansion, as the second substantially transparent encapsulant 150 does not cover the first substantially transparent encapsulant 140 completely leaving behind a gap 144 that is either exposed or filled by a flexible material. The gap 144 may be configured to avoid thermal stress caused by the second substantially transparent encapsulant 150. The gap 144 that is exposed may attract dust in a longer term. Therefore, the gap 144 may be made as small as possible. At least for the reason that the gap 144 is not accessible by a user, the light-emitting device 100 is less susceptible to attracting dust during the assembly period.

Optionally, the light-emitting device 100 may further comprise a third substantially transparent encapsulant 160. The third substantially transparent encapsulant 160 may be substantially similar to the second substantially transparent encapsulant 150 and may comprise a substantially similar composition of encapsulant. The third substantially transparent encapsulant 160 may comprise a plurality of second encapsulant islands 161 covering the first substantially transparent encapsulant 140 that is exposed and not covered by the plurality of first encapsulant islands 151.

Specifically, the first substantially transparent encapsulant 140 may comprise a filler encapsulant portion 144 filling up the gap between the plurality of first encapsulant islands 151. The filler encapsulant portion 144 may be surrounding each of the plurality of first encapsulant islands 151. The filler encapsulant 144 and the first substantially transparent encapsulant 140 may comprise substantially similar components in a substantially similar composition. In one embodiment, the filler encapsulant 144 and the first substantially transparent encapsulant 140 may be made from similar epoxy or silicone. The filler encapsulant 144 may be configured to provide a substantially flat surface 145 so as to receive the third substantially transparent encapsulant 160. As shown in FIG. 1, the plurality of second encapsulant islands 161 may be formed on top of the filler encapsulant 144.

The plurality of second encapsulant islands 161 may be formed such that the plurality of second encapsulant islands 161 and the plurality of first encapsulant islands 151 do not overlap substantially with the each other so as to increase reliability of the light-emitting device. In one embodiment, the overlap between the plurality of second encapsulant islands 161 and the plurality of first encapsulant islands 151 may be less than 5% of the total illumination surface 142. In addition, the plurality of second encapsulant islands 161 and the plurality of first encapsulant islands 151 may be arranged to cover and shield the first substantially transparent encapsulant 140 and the filler encapsulant 144 collectively such that the first substantially transparent encapsulant 140 and the filler encapsulant 144 are not exposed externally.

The light-emitting device 100 may form a portion of a lighting system, a lighting apparatus, or proximity sensors, motion encoders or other opto-electronic devices.

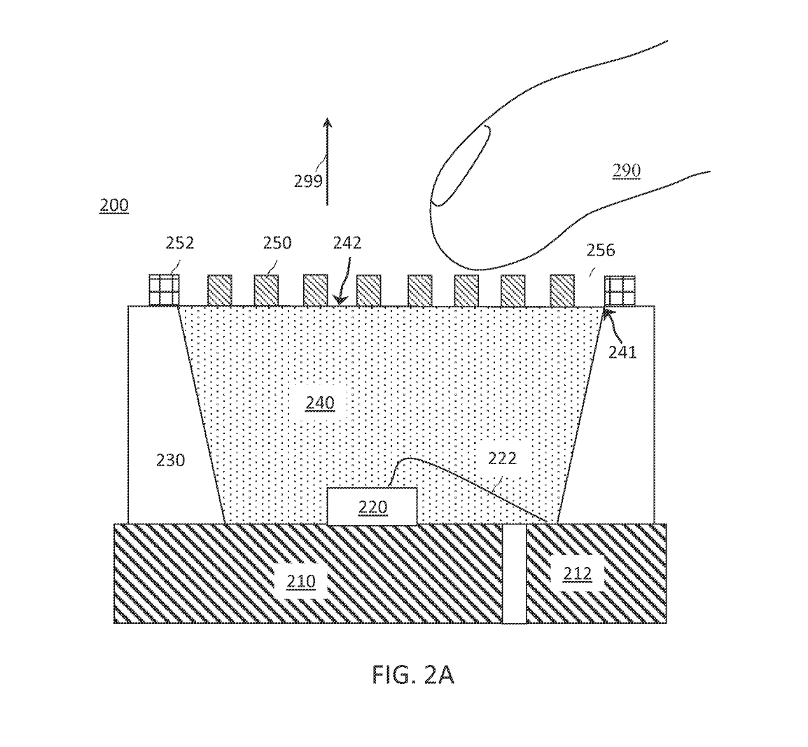

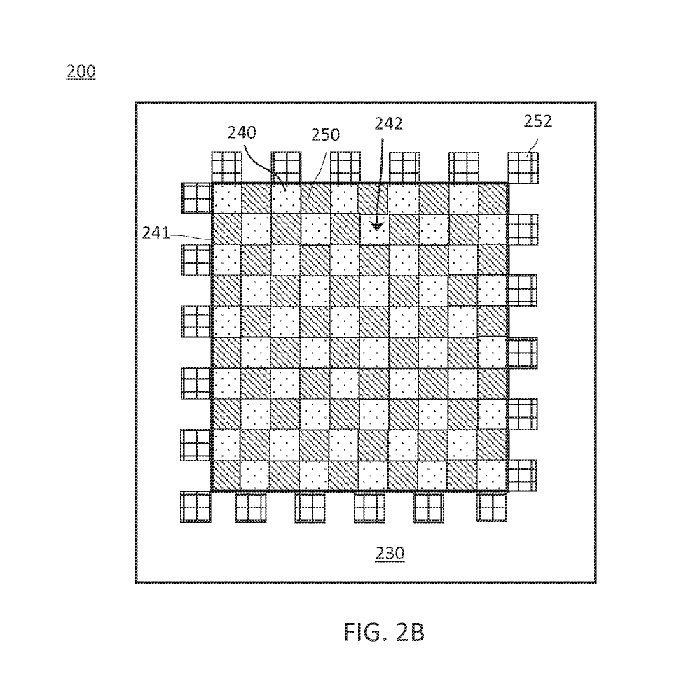

FIG. 2A illustrates a cross-sectional view of a light-emitting device 200. A top view of the light-emitting device 200 is shown in FIG. 2B. The light-emitting device 200 may comprise a body 210, 212, 230, a light source die 220, a first substantially transparent encapsulant 240 having an illumination surface 242, and a second substantially transparent encapsulant 250, 252. The second substantially transparent encapsulant 250, 252 may be formed on the illumination surface 242, and optionally a portion of the body 230. The body 210, 212, 230 may comprise a plurality of conductors 210, 212 and a reflective wall 230. The plurality of conductors 210, 212 may be a metal substrate configured to provide support to the entire light-emitting device 200. In the embodiment shown in FIG. 2A, the plurality of conductors 210, 212 may comprise a die attach pad 210, and a metal 212 configured to receive a wire bond 222. The wire bond 222 may be distanced away from the second substantially transparent encapsulant 250, 252. The light source die 220 may be attached on the die attach pad 210 so as to emit light towards the illumination direction 299. The reflective wall 230 may define a substantially cup shape so as to direct light towards an illumination direction 299.

The first substantially transparent encapsulant 240 may be encapsulating the light source die 220, the wire bond 222 and at least a portion of the plurality of conductors 210, 212. The illumination surface 242 may be substantially flat and may be facing the illumination direction 299. Light emitted from the light source die 220 may be directed towards the illumination direction 299 through the illumination surface 242. The top view of the illumination surface 242 of the light-emitting device 200 may be substantially a rectangular or square shape as depicted in FIG. 2B, but in another embodiment, the illumination surface 242 may have a substantially circular or oval shape. It should also be appreciated that non-uniform polygons may be used without departing from the scope of the present disclosure.

The second substantially transparent encapsulant 250, 252 may be formed on the illumination surface 242 of the first substantially transparent encapsulant 240. The second substantially transparent encapsulant 250 may be less tacky or less sticky compared to the first substantially transparent encapsulant 240. The second substantially transparent encapsulant 250, 252 may have a lower coefficient of static friction relative to the first substantially transparent encapsulant 240. The first substantially transparent encapsulant 240 and the second substantially transparent encapsulant 250, 252 may be made from silicone or epoxy that may differ in composition and/or curing profile. The first substantially transparent encapsulant 240 may be soft relative to the second substantially transparent encapsulant 250, 252. In addition, the first substantially transparent encapsulant 240 may have a tendency to attract an external object, such as dust to its surface as compared to the second substantially transparent encapsulant 250, 252.

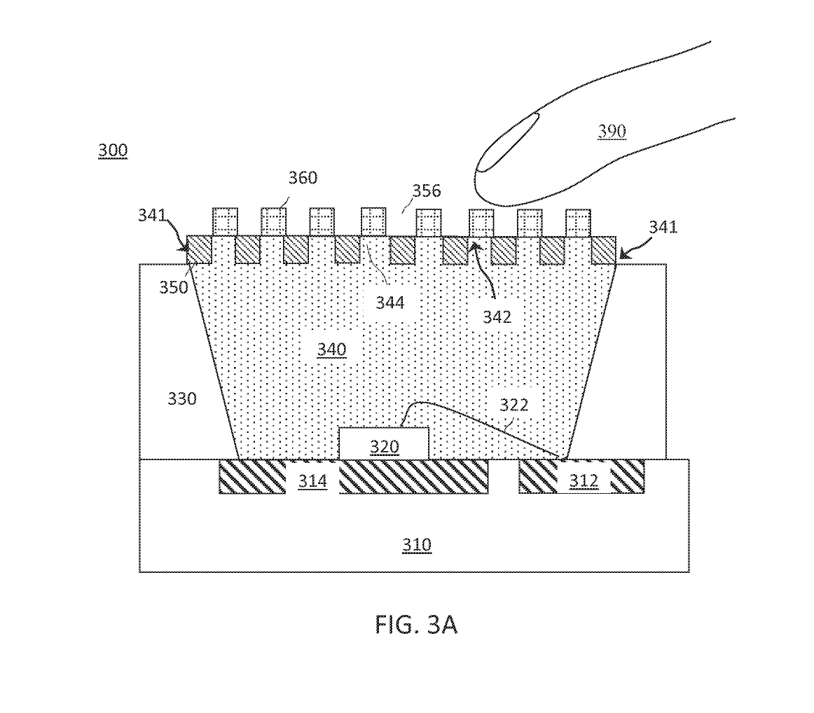

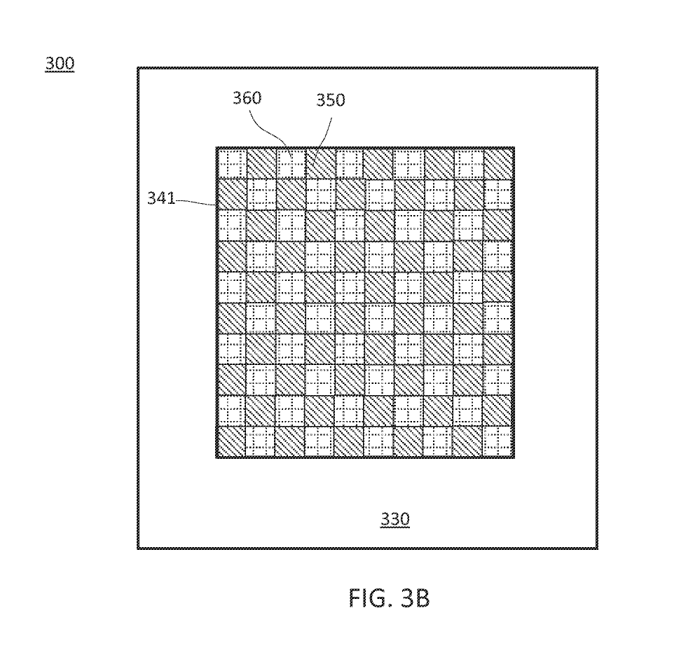

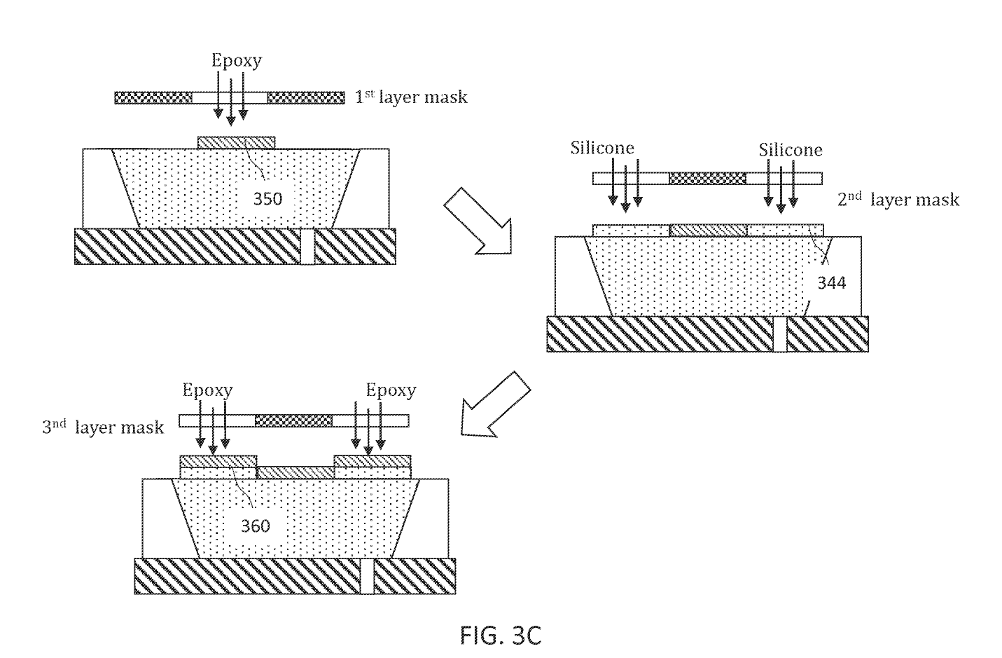

The second substantially transparent encapsulant 250, 252 may comprise a plurality of hardened elements 250 formed on the illumination surface 242, and optionally an additional plurality of hardened elements 252 formed on a portion of the body 230. As shown in FIG. 2B, the illumination surface 242 may have an outer perimeter 241 circumscribing the illumination surface 242 there between. Each of the plurality of hardened elements 250, and the additional plurality of hardened elements 252, may be substantially in direct contact with the outer perimeter 241. In this way, at least one or both of the plurality of hardened elements 250 and the additional plurality of hardened elements 252 may surround each of the exposed portions of the illumination surface 242. This arrangement may enable the illumination surface 242 that may be tacky to be shielded substantially and not accessible by an external user 290. This may reduce chances of the illumination surface 242 to attract dust. Dust may be accumulated over a length period of use as the illumination surface 242 that is tacky is exposed. However, introducing the second substantially transparent encapsulant 250, 252 may have substantially reduced the exposed portion of the illumination surface 242. The exposed portion of the illumination surface 2424 may be eliminated substantially in the embodiment shown in FIG. 3A.

FIG. 3A illustrates a cross-sectional view of a light-emitting device 300. A top view of the light-emitting device 300 is shown in FIG. 3B. The light-emitting device 300 may comprise a substrate 310, a plurality of conductors 312, 314 formed on the substrate 310, a body 330, a light source die 320, a first substantially transparent encapsulant 340 having an illumination surface 342, a second substantially transparent encapsulant 350 and a third substantially transparent encapsulant 360. The light-emitting device 300 may be substantially similar to the light-emitting device 200 but differ at least in that the light-emitting device 300 may comprise the substrate 310 and the third substantially transparent encapsulant 360. The second substantially transparent encapsulant 350 and the third substantially transparent encapsulant 360 may, in combination, entirely cover the illumination surface 342 of the first substantially transparent encapsulant 340. The second substantially transparent encapsulant 350 and the third substantially transparent encapsulant 360 may comprise substantially similar composition of epoxy or silicone. In other words, the second substantially transparent encapsulant 350 and the third substantially transparent encapsulant 360 may be substantially similar but cured or manufactured in different stages of a manufacturing process. Compared to the first substantially transparent encapsulant 340, the second substantially transparent encapsulant 350 and the third substantially transparent encapsulant 360 may be hardened, more brittle, and may have a lower coefficient of static friction relative to the first substantially transparent encapsulant 340.

This arrangement may be beneficial in that the first substantially transparent encapsulant 340 may be prevented from attracting dust almost completely. In addition, each of the second substantially transparent encapsulant 350 and the third substantially transparent encapsulant 360 may not cover the illumination surface of the first substantially transparent encapsulant 340 entirely by having gaps 344, 356 respectively therebetween. For example, the second substantially transparent encapsulant 350 may comprise a plurality of encapsulant islands 350 separated by a filler encapsulant 344 that may be formed by the first substantially transparent encapsulant 340. Similarly, the third substantially transparent encapsulant 360 may comprise a plurality of encapsulant islands 360 separated by gap 356 that may be air.

The plurality of encapsulant islands 350 may be arranged within an outer perimeter 341 of the illumination surface 342. A portion of the plurality of encapsulant islands 350 may be in direct contact with the outer perimeter 341. In another embodiment, the filler encapsulant 344 may be different from the first substantially transparent encapsulant 340 but may have similar hardness and/or similar thermal expansion behavior as the first substantially transparent encapsulant 340. With this arrangement, the second substantially transparent encapsulant 350 may be interposed between the filler encapsulant 344. When the light-emitting device 300 is subjected to mechanical or thermal stress, the second substantially transparent encapsulant 350 may be prevented from cracked or damaged because the filler encapsulant 344 may absorb the stress.

The plurality of encapsulant islands 360 may be arranged within the outer perimeter 341 of the illumination surface 342 as shown in FIG. 3B. Recall that the plurality of encapsulant islands 360 may be interposed with the gap 356 on the illumination surface 342. Similar to the discussion above, as the third substantially transparent encapsulant 360 may be hardened elements that may be brittle, this arrangement may enable the third transparent encapsulant 360 to withstand higher stress. When the light-emitting device 300 is under stress, the gap 356 may provide space for thermal expansion. Consequently, stress on the third substantially transparent encapsulant 360 may be substantially reduced. Recall that the second substantially transparent encapsulant 350 and the third substantially transparent encapsulant 360 combinedly covers the first substantially transparent encapsulant 340 that may be tacky. This may completely prevent the illumination surface 342 from being accessible by an external object 390 and may prevent the light-emitting device 300 from collecting dust.

FIG. 3C illustrates a manufacturing process showing how the second substantially transparent encapsulant 350 and the third substantially transparent encapsulant 360 can be formed. First, the shape of the second substantially transparent encapsulant 350 and the third substantially transparent encapsulant 360 may be determined For example, in the embodiment shown in FIG. 3C, the matrix may be determined so as to design a first layer mask, a second layer mask and a third layer mask. As shown in FIG. 3C, the second substantially transparent encapsulant 350 may be formed on the first substantially transparent encapsulant 340 using the first layer mask through screen print or jetting method. To avoid smearing of epoxy, the silicone surface may need pre-treatment to increase the surface tension. Alternatively, a fast ultra-violet cure of epoxy or silicone may be utilized. The second substantially transparent encapsulant 350 may be cured after being formed. Next, the filler encapsulant 344 may be formed using the second layer mask through screen print or jetting method described above. The filler encapsulant 344 may be cured prior to the next step. Subsequently, the third substantially transparent encapsulant 360 may be formed using the third layer mask.

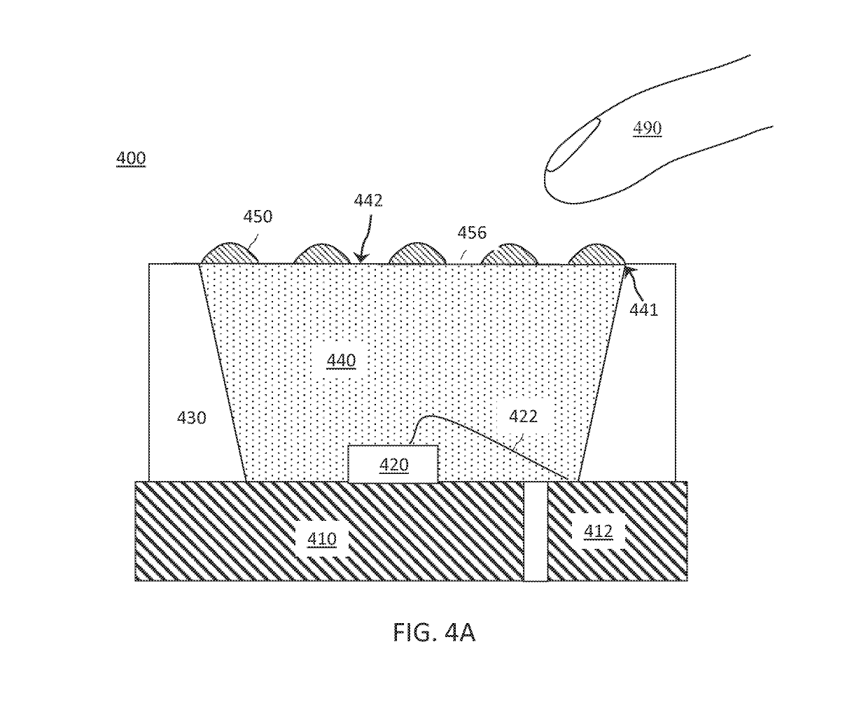

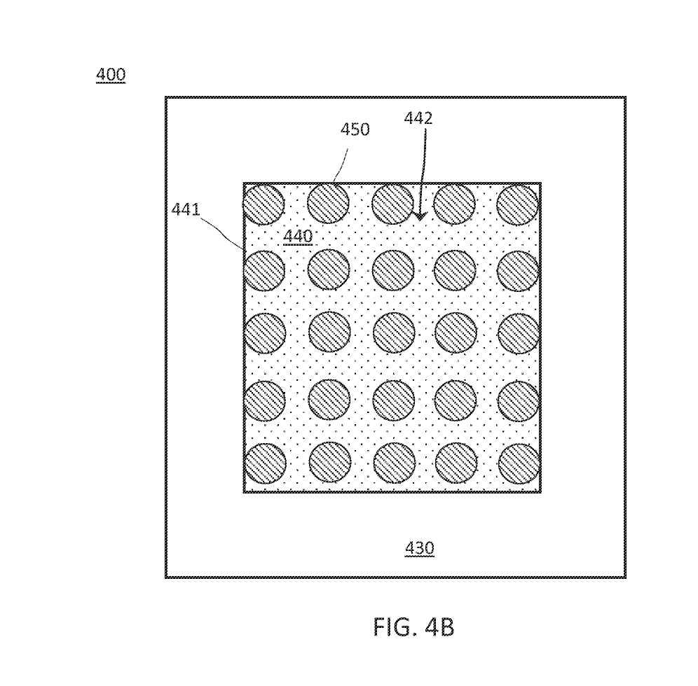

The plurality of encapsulant islands 350, 360 shown in FIG. 3A and FIG. 3B may be substantially square or rectangular shape. However, in another embodiment, the plurality of encapsulant islands 350, 360 may be formed in other shapes depending on the convenience of manufacturing process. For example, FIG. 4A illustrates a cross-sectional view of a light-emitting device 400 having droplets of a second substantially transparent encapsulant 450 that may be in substantially circular or oval shape. A top view of the light-emitting device 400 is shown in FIG. 4B. The light-emitting device 400 may comprise a body 410, 412, 430, a light source die 420, a first substantially transparent encapsulant 440 having an illumination surface 442, and a second substantially transparent encapsulant 450 formed on the illumination surface 442. The body 410, 412, 430 may comprise a plurality of conductors 410, 412 and a reflective wall 430. The plurality of conductors 410, 412 may be a metal substrate configured to provide support to the entire light-emitting device 400.

The light-emitting device 400 may be substantially similar to the light-emitting device 200 but may at least differ in the fact that the second substantially transparent encapsulant 450 may comprise a plurality of droplets of hardened elements 450 rather than a rectangular structure shown in FIG. 2A. The plurality of droplets of hardened elements 450 may be drawn substantially larger than actual size in the embodiment shown in FIG. 4A. The plurality of droplets of hardened elements 450 may be covering the illumination surface 442 of the first substantially transparent encapsulant 440. The plurality of droplets of hardened elements 450 may be substantially transparent and cover more than 75% of the illumination surface 442 in one embodiment. In another embodiment, the plurality of droplets of hardened elements 450 may be substantially transparent and cover more than 90% of the illumination surface 442. It may be beneficial to cover majority of the surfaces such as by 75% or 90% so that the majority surface of the illumination surface 442 does not collect dust.

The plurality of droplets of hardened elements 450 may be spaced apart from each other such that the illumination surface 442 may not be accessible by an external object 490. In addition, the plurality of droplets of hardened elements 450 may be arranged within an outer perimeter 441 of the illumination surface 442. A portion of the plurality of droplets of hardened elements 450 may be in direct contact with the outer perimeter 441. The arrangement and the shape of the plurality of droplets of hardened elements 450 may be beneficial in that the shape may form a lens to collimate light.

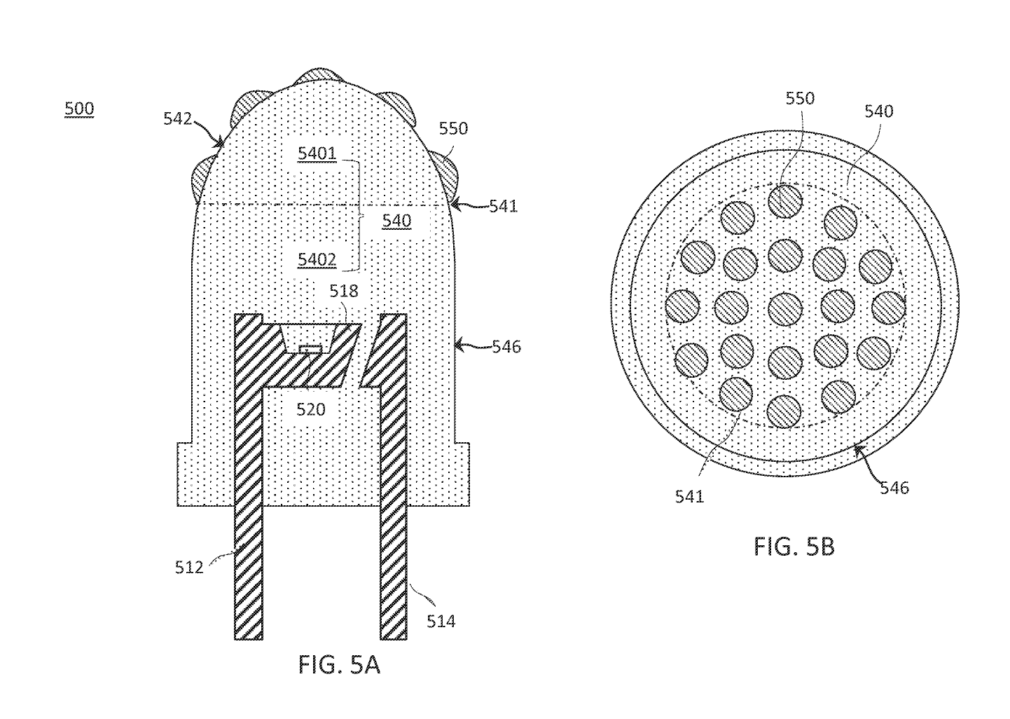

FIG. 5A illustrates a cross-sectional view of a lamp-LED type of light-emitting device 500. FIG. 5B illustrates a top view of the light-emitting device 500 shown in FIG. 5A. The light-emitting device 500 may comprise a plurality of conductors 512, 514, a light source die 520, a first substantially transparent encapsulant 540 having an illumination surface 542, and a second substantially transparent encapsulant 550 formed on the illumination surface 542. In the embodiment shown in FIG. 5A, the second substantially transparent encapsulant 550 may be a plurality of encapsulant islands 550 that may be spaced apart from each other. The plurality of encapsulant islands 550 may be drawn substantially larger than actual size in the embodiment shown in FIG. 5A to illustrate various aspect of the plurality of encapsulant islands 550. The actual size of the encapsulant islands 550 may be tiny droplets that may be less than 200 microns. The plurality of encapsulant islands 550 may be arranged within a boundary or an outer perimeter 541 of the illumination surface 542. The boundary or the outer perimeter of the illumination surface 542 may be less clearly identifiable compared to the light-emitting devices 200, 300, 400 shown in previous embodiments. However, the outer perimeter 541 may be identified as a boundary between a lens portion 5401 and a body portion 5402 of the first substantially transparent encapsulant 540.

As shown in FIG. 5A, the first substantially transparent encapsulant 540 may have a side surface 546. The body portion 5402 of the first substantially transparent encapsulant 540 may be surrounded by the side surface 546. The body portion 5402 of the first substantially transparent encapsulant 540 may be cylindrical shape. In the embodiment shown in FIG. 5A, the plurality of conductors 512, 514 and the body portion 5402 of the first substantially transparent encapsulant 540 may be configured to provide structural support for other components of the light-emitting device 500, and therefore, may form a body of the light-emitting device 500.

The lens portion 5401 of the substantially transparent encapsulant 540 may be formed adjacent to the body portion 5402. The lens portion 5401 and the body portion 5402 may be integrally formed. The lens portion 5401 of the first substantially transparent encapsulant 540 may be configured to direct light towards an illumination direction. In the embodiment shown in FIG. 5A, the illumination surface 542 may be formed on the lens portion 5401 and not on the body portion 5402. The illumination surface 542 may be a curvature and may be distinguishable from the side surface 546. The outer perimeter of the illumination surface 542 may be the boundary of the lens portion 5401 and the body portion 5402 of the substantially transparent encapsulant 540. In some embodiments, the body portion 5402 is in direct contact with the conductors 512, 514 whereas the lens portion 5401 is not in direct contact with the conductors 512, 514. As shown in FIG. 5B, the lens portion 5401 may be substantially circular.

Referring to FIG. 5A, the light-emitting device 500 shown in FIG. 5A may be a lamp LED, and the plurality of conductors 512, 514 may comprise two leads 512, 514 encapsulated partially by the first encapsulant. For lamp LED, plastic leaded chip carrier packages or other packages formed using a molding process, the plurality of conductors 512, 514 may be leads forming part of lead frames. As shown in FIG. 5A, a portion of the plurality of conductors 512 may be made larger and may form the reflective cup 518. The reflector cup 518 may comprise an opening located on a top end of the reflector cup 518. The reflector cup 518 may be shaped so as to direct light towards the illumination direction.

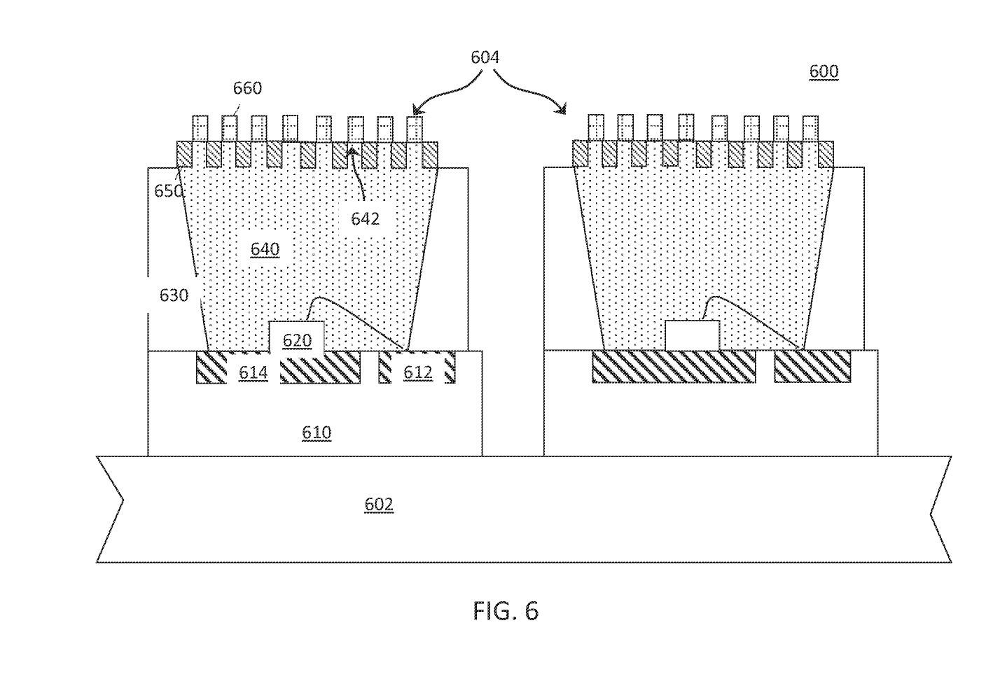

FIG. 6 illustrates an embodiment of a display system 600. The display system 600 may be a large-scale display system used in stadiums or public area. The display system 600 may comprise a substrate 602, and a plurality of light-emitting devices 604 attached on the substrate 602. The plurality of light-emitting devices 604 may be the light-emitting devices 100, 200, 300, 400, 500 illustrated in previous embodiments, or any other light-emitting devices (not shown) illustrated within the teaching of various embodiments discussed previously.

Each of the plurality of the light-emitting devices 604 may comprise a body 630, a substrate 610 having a plurality of conductors 612, 614, a light source die 620, a first substantially transparent encapsulant 640 having an illumination surface 642, a second substantially transparent encapsulant 650 and a third substantially transparent encapsulant 660.

The first substantially transparent encapsulant 640 may be encapsulating and surrounding the light source die 620. The second substantially transparent encapsulant 650 may comprise a plurality of hardened encapsulant islands 650 covering at least partially the first substantially transparent encapsulant 640. The first substantially transparent encapsulant 640 may be stickier than the plurality of hardened encapsulant islands 650 made from the second substantially transparent encapsulant 650. Similarly, the first substantially transparent encapsulant 640 may be stickier than the third substantially transparent encapsulant 660. Sticky may mean tendency to stick to things. A sticky object may be glutinous and viscous. The first substantially transparent encapsulant 640 that is stickier may attract dust more easily compared to the second substantially transparent encapsulant 650 and the third substantially transparent encapsulant 660.

Different aspects, embodiments or implementations may, but need not, yield one or more of the following advantages. For example, the arrangement of the plurality of encapsulant islands may be advantageous for less likely to attract or collect dust. Although specific embodiments of the invention have been described and illustrated herein above, the invention should not be limited to any specific forms or arrangements of parts so described and illustrated. For example, light source die described above may be LEDs die or some other future light source die as known or later developed without departing from the spirit of the invention. Likewise, although light-emitting devices were discussed, the embodiments are applicable to optical devices such as proximity sensor and encoders as well as component level such as a light-source packaging to produce the light-emitting devices. The light-emitting device shown in various embodiments may be optical devices such as proximity sensors, encoders, or other devices having a component capable to emit a radiation. The scope of the invention is to be defined by the claims appended hereto and their equivalents.

What is claimed is:

1. A light-emitting device, comprising:
a light source die;
a first substantially transparent encapsulant surrounding the light source die; and
a second substantially transparent encapsulant at least partially covering the first substantially transparent encapsulant and exposing a portion of the first substantially transparent encapsulant, wherein the second substantially transparent encapsulant is less tacky as compared to the first substantially transparent encapsulant.

2. The light-emitting device of claim 1, wherein the second substantially transparent encapsulant partially covers the first substantially transparent encapsulant such that the first substantially transparent encapsulant is exposed externally, but not accessible by an external user.

3. The light-emitting device of claim 1, wherein the second substantially transparent encapsulant is substantially harder as compared to the first substantially transparent encapsulant.

4. The light-emitting device of claim 1, wherein the second substantially transparent encapsulant comprises a plurality of first encapsulant islands.

5. The light-emitting device of claim 4, wherein the plurality of first encapsulant islands are distance away from each other.

6. The light-emitting device of claim 4, wherein the plurality of first encapsulant islands are distance away from each other by less than about 3 mm such that the first substantially transparent encapsulant is exposed externally but not accessible by a user.

7. The light-emitting device of claim 4, further comprising a third substantially transparent encapsulant that is substantially similar to the second substantially transparent encapsulant, wherein the third substantially transparent encapsulant comprises a plurality of second encapsulant islands covering the first substantially transparent encapsulant that is exposed and not covered by the plurality of first encapsulant islands.

8. The light-emitting device of claim 7, wherein the first substantially transparent encapsulant comprises a filler encapsulant surrounding each of the plurality of first encapsulant islands.

9. The light-emitting device of claim 8, wherein the plurality of second encapsulant islands is formed on the filler encapsulant.

10. The light-emitting device of claim 8, wherein the filler encapsulant and the first substantially transparent encapsulant comprise substantially similar components in a substantially similar composition.

11. The light-emitting device of claim 7, wherein the plurality of second encapsulant islands and the plurality of first encapsulant islands do not overlap with the each other.

12. The light-emitting device of claim 4, wherein the light-emitting device has an illumination surface, and wherein the plurality of first encapsulant islands covers more than 50% of the illumination surface.

13. The light-emitting device of claim 4, wherein the plurality of first encapsulant islands are arranged in a uniformly-spaced two-dimensional matrix.

14. The light-emitting device of claim 1, wherein the second substantially transparent encapsulant comprises a plurality of transparent droplets distanced away from one another.

15. The light-emitting device of claim 1 forms a portion of a lighting system.

16. A light-emitting device, comprising:
a body;
a light source die attached on a first portion of the body, the light source die configured to emit light towards an illumination direction;
a first substantially transparent encapsulant encapsulating the light source die and at least the first portion of the body;
an illumination surface of the first substantially transparent encapsulant, the illumination surface facing the illumination direction; and
a plurality of hardened elements formed on the illumination surface of the first substantially transparent encapsulant, wherein the plurality of hardened elements have a lower coefficient of static friction relative to the first substantially transparent encapsulant.

17. The light-emitting device of claim 16, wherein the light-emitting device further comprises an additional plurality of hardened elements formed on the body surrounding the illumination surface.

18. The light-emitting device of claim 17, wherein the illumination surface of the first substantially transparent encapsulant has an outer perimeter and the additional plurality of hardened elements formed on the body are in direct contact with the outer perimeter.

19. The light-emitting device of claim 16, wherein the illumination surface of the first substantially transparent encapsulant has an outer perimeter and the plurality of hardened elements are in direct contact with the outer perimeter.

20. A display system, comprising:
a substrate; and
a plurality of light-emitting devices attached on the substrate, wherein each of the plurality of light-emitting devices comprises:
a light source die;
a first substantially transparent encapsulant surrounding the light source die; and
a plurality of hardened encapsulant islands covering at least partially the first substantially transparent encapsulant, wherein the first substantially transparent encapsulant is stickier than the plurality of hardened encapsulant islands.
